(19) United States
(12) Patent Application Publication
(10) Pub. No.: US 2026/0202691 A1
(43) Pub. Date: Jul. 16, 2026

(54) PHOTODETECTOR, MODULATOR, SEMICONDUCTOR DEVICE AND SEMICONDUCTOR APPARATUS

(71) Applicant: Black Semiconductor GmbH, Aachen (DE)

(72) Inventor: Daniel SCHALL, Aachen (DE)

(21) Appl. No.: 19/560,319

(22) Filed: Mar. 9, 2026

Related U.S. Application Data
(62) Division of application No. 17/910,179, filed on Feb. 23, 2021.

(30) Foreign Application Priority Data
Mar. 9, 2020 (DE) 202020101285.1

(51) Int. Cl. G02F 1/01; G02F 1/19; H10F 30/28

(52) U.S. Cl. CPC G02F 1/01; G02F 1/19; H10F 30/2863

(57) ABSTRACT

The present invention relates to a photodetector (3) comprising: a longitudinal portion (12) of a waveguide (11) which comprises or is formed by two waveguide segments (12a, 12b), which extend at least substantially parallel to one another in the longitudinal direction and are preferably distanced from one another in the transverse direction, forming a gap (14) between them; and an active element (13), which overlies the longitudinal portion (12) of the waveguide and comprises at least one material or consists of at least one material that absorbs electromagnetic radiation of at least one wavelength and generates an electric photosignal as a result of the absorption, the two waveguide segments (12a, 12b) each being in contact, at least in some portions, on at least one side, in particular on the side facing the active element (14), with a gate electrode (15a, 15b) which preferably comprises silicon or consists of silicon.

The invention relates to a photodetector and a modulator. Furthermore, the invention relates to a semiconductor apparatus having a chip and at least one photodetector and/or modulator and to a semiconductor device having a wafer and at least one photodetector and/or modulator.

Electro-optical devices, for example photodetectors or electro-optical modulators, are known from the prior art, which electro-optical devices comprise a waveguide or longitudinal section of such a waveguide with several waveguide segments extending in longitudinal direction and at least substantially parallel to one another and—in the case of a photodetector—one or—in the case of an electro-optical modulator—two films of graphene as active elements. Such are disclosed, for example, in U.S. Pat. No. 9,893,219B 2 .

The known photodetectors and modulators have proven themselves in principle. However, there is a need for further, alternatively designed photodetectors and modulators which can be fabricated with reasonable effort and are characterized by an optimal mode of operation.

It is therefore an object of the present invention to provide alternatively designed photodetectors and modulators which fulfil these requirements.

This object is solved with respect to a photodetector by the measures mentioned in claims 1 and 6 and with respect to a modulator by the measures mentioned in claims 9, 10 and 11.

According to a first aspect of the invention, a photodetector is provided which comprises a longitudinal section of a waveguide, which comprises or is formed by two waveguide segments extending in the longitudinal direction and at least substantially parallel to one another, the waveguide segments being spaced apart from one another, preferably in the transverse direction, forming a gap extending therebetween, and an active element, which overlaps the longitudinal section of the waveguide and comprises or consists of at least one material which absorbs electromagnetic radiation of at least one wavelength and, as a result of the absorption, generates an electrical photosignal, wherein the two waveguide segments are in contact, respectively on at least one side, in particular on the side facing the active element, at least in sections with a gate electrode preferably comprising silicon or consisting of silicon.

A method according to the invention for fabricating such a detector comprises, for example, that a waveguide material is applied, preferably deposited, in particular on a wafer or on a coat provided on or above a wafer, and a gate electrode material, preferably silicone, is applied, in particular deposited, and a structuring is carried out in order to obtain the two waveguide segments with the gap therebetween and the gate electrodes, and the active element is provided.

By means of the gate electrodes, a pn-junction can be realized in the active element during operation. By arranging the pn-junction in the optical mode region, an optimal overlap between the absorbing material and the active region of the photodetector is achieved.

In an advantageous embodiment, it is provided that the gate electrodes are each in contact at their underside with the upper side of a waveguide segment and are each in contact with their upper side with the underside of a dielectric coat provided between the active element and the waveguide segments, which dielectric coat expediently comprises at least one dielectric material or consists of at least one dielectric material. Suitable materials have proven to be, for example, silicon dioxide (SiO₂) as well as aluminium oxide (AL₂O₃). Alternatively to the term dielectric material, the term dielectric is also used. The dielectric coat can also be referred to as gate dielectric.

In a further development, the active element may have been or may be arranged on the upper side of the dielectric coat. It may have been or may be fabricated thereon.

In a preferred embodiment, the dielectric coat may be characterized on its upper side by a roughness in the range of 1.0 nm RMS to 0.1 nm RMS, in particular 0.6 nm RMS to 0.1 nm RMS, preferably 0.4 nm RMS to 0.1 nm RMS. The abbreviation RMS stands for root mean squared. The RMS roughness is also referred to in German as “quadratische Rauheit”. An upper side with a roughness in this range has proven particularly suitable in the case where the active element is provided on the upper side of the dielectric coat, in particular fabricated thereon.

The thickness of the dielectric coat may, for example, be in the range from 10 to 20 nm.

Preferably, the gate electrodes comprise or consist of a material which is transparent for electromagnetic radiation of at least one wavelength, preferably at least one wavelength range, and/or is electrically conductive.

Further preferably, the gate electrodes comprise or consist of at least one material which is transparent to electromagnetic radiation of a wavelength of 850 nm and/or 1310 nm and/or 1550 nm. Particularly preferably, it is transparent to electromagnetic radiation in the wavelength range from 800 nm to 900 nm and/or from 1260 nm to 1360 nm (so-called original band or O-band for short) and/or 1360 nm to 1460 nm (so-called extend band or E-band for short) and/or 1460 nm to 1530 nm (so-called short band or S-band for short) and/or from 1530 nm to 1565 nm (so-called conventional band or C-band for short) and/or 1565 nm to 1625 nm (so-called long band or L-band for short). These bands are known from the field of communication engineering.

This applies accordingly with preference to the gate electrode material used in the fabrication method.

Silicon has proven to be a particularly suitable material for the gate electrodes. It can be polysilicon. Indium tin oxide (ITO) may also be considered. The material(s), of which the gate electrodes consist or from which the gate electrodes are fabricated, can also be doped.

The respective gate electrode can, for example, be a coat provided on the side of the respective waveguide segment of the waveguide longitudinal section facing the active element, particularly preferably a coat which is or was fabricated on the respective waveguide segment.

Furthermore, it can be provided that the gate electrodes are fabricated or have been fabricated by deposition, in particular by chemical vapor deposition (CVD), preferably low-pressure chemical vapor deposition (LPCVD) and/or plasma-enhanced chemical vapor deposition (PECVD), and/or by physical vapor deposition (PVD) of a coating material.

There are various prior art chemical vapor deposition processes, all of which can have been or can be used in the context of the present invention. Common to all of them is usually a chemical reaction of introduced gases, which leads to a deposition of the desired material.

Also with regard to physical vapor deposition, all variants known in the prior art may have been or may be used. Purely by way of example, electron beam evaporation, in which material is melted and evaporated by means of an electron beam, and thermal evaporation, in which material is heated to the melting point by means of a heater and evaporated onto a target substrate, as well as sputter deposition, in which atoms are knocked out of a material carrier by means of a plasma and deposited onto a target substrate, may be mentioned.

Alternatively or in addition to the above-mentioned deposition processes, atomic layer deposition (ALD) can be used to obtain the gate electrode. In this process, insulating or conductive materials (dielectrics, semiconductors or metals) are sequentially deposited atomic layer by atomic layer. A transfer process may also be used or have been used.

In a further development, it can also be provided that each of the two gate electrodes is assigned an interconnection element in contact therewith, and preferably one of the interconnection elements extends through one of the waveguide segments respectively. The deposition may be followed or have been followed by a suitable structuring process, which may include, for example, lithography and/or etching. The interconnection elements are preferably vertical electrical interconnections, also known in English as Vertical Interconnect Access, or Via or VIA for short. VIAs are usually defined by lithography and are dry-chemically etched, in particular by reactive ion etching (RIE for short). Thereafter, metallization is preferred and the metallized surface is structured by CMP (Damascene process) or by lithography and RIE.

Reactive ion etching is a dry etching process, in which selective and directional etching of a substrate surface is usually achieved by means of special gaseous chemicals that are excited to form a plasma. A resist mask can be used to protect parts that are not to be etched. The etch chemistry and the parameters of the process usually determine the selectivity of the process, i.e., the etch rates of different materials. This property is crucial to limit an etching process in depth and thus define coats separately from each other.

Expediently, the interconnection elements comprise or consist of at east one electrically conductive material, in particular a metal, such as copper and/or aluminium and/or tungsten.

In another advantageous embodiment, it is further provided that the active element overlaps the two waveguide segments and the gap lying therebetween at least in sections, in particular in the transverse direction. By transverse direction expediently is to be understood as the direction oriented orthogonally to the longitudinal direction of the longitudinal section of the waveguide.

According to a second aspect of the invention, there is provided a photodetector comprising a longitudinal section of a waveguide, and an active element comprising or consisting of at least one material which absorbs electromagnetic radiation of at least one wavelength and, as a result of the absorption, generates an electrical photosignal, wherein two carrier elements are arranged on opposite sides of the longitudinal section of the waveguide spaced therefrom forming two gaps, wherein the two gaps are free of material, and wherein the active element overlaps the longitudinal section of the waveguide and the two gaps and at least sections of the two carrier elements, in particular in the transverse direction. Preferably, the two carrier elements are spaced apart from the longitudinal section in the transverse direction.

A method according to the invention for fabricating such a detector comprises, for example, applying, preferably depositing, a waveguide material in particular on a wafer or on a coat provided on or above a wafer, and structuring to obtain the two gaps and the longitudinal section of the waveguide and the carrier elements, and providing the active element above the longitudinal section of the waveguide and the carrier elements.

The gaps, which are free of material, are given in particular by regions from which material has been removed by an etching process and subsequently no new material has been provided, for example deposited. They can be filled with air or another gas or be under vacuum. However, there is no solid material in them. Vacuum is preferably to be understood as an evacuated space, for example, by pumping.

In a preferred embodiment, the active element lies on the upper side of the longitudinal section of the waveguide facing the active element and/or on the upper side of the carrier elements facing the active element.

The carrier elements may be of the same material as the longitudinal section of the waveguide, this being understood as exemplary. TiO₂ and/or Si, for example, have proven to be suitable materials for the carrier elements. Any other materials suitable for waveguides may also be considered.

It may be that the active element comprises or consists of at least one material, which can absorb electromagnetic radiation of a wavelength of 850 nm and/or 1310 nm and/or 1550 nm and generate a photosignal as a result of the absorption. It is particularly preferred that it absorbs electromagnetic radiation in the wavelength range from 800 nm to 900 nm and/or from 1260 nm to 1360 nm (so-called original band or O-band for short) and/or from 1360 nm to 1460 nm (so-called extended band or E-band for short) and/or from 1460 nm to 1530 nm (so-called short band or S-band for short) and/or from 1530 nm to 1565 nm (so-called conventional band or C-band for short) and/or from 1565 nm to 1625 nm (so-called long band or-L band for short) and can generate a photosignal as a result of the absorption.

It has proven to be particularly suitable if the at least one material of the active element which absorbs electromagnetic radiation of at least one wavelength and generates an electrical photosignal as a result of the absorption is graphene and/or at least one dichalcogenide, in particular two-dimensional transition metal dichalcogenide, and/or heterostructures of two-dimensional materials and/or germanium and/or at least one electro-optical polymer and/or silicon and/or at least one compound semiconductor, in particular at least one III-V semiconductor and/or at least one II-VI semiconductor.

In particular, a photodetector may serve for signal conversion back from the optical to the electronic world.

According to a third aspect of the invention, there is provided a modulator, in particular an electro-optical modulator, comprising a longitudinal section of a waveguide, which comprises or is formed by four waveguide segments extending in the longitudinal direction and at least substantially parallel to one another, and two active elements comprising at least one material or consisting of at least one material whose refractive index changes as a function of a voltage and/or the presence of charge and/or an electric field, or one such active element and an electrode, wherein a lower one of the waveguide segments is arranged between the two active elements or between the active element and the electrode, a middle one of the waveguide segments is arranged above the two active elements or above the active element and the electrode, and the two remaining, upper waveguide segments are arranged above the middle waveguide segment, wherein the two upper waveguide segments are spaced apart from each other, preferably in the transverse direction, forming a gap extending therebetween.

Then, in particular, there may be a sandwich-like structure comprising, from bottom to top, an active element or electrode, then the lower waveguide segment of the longitudinal section of the waveguide, then the second active element or electrode, then the middle waveguide segment of the longitudinal section of the waveguide, and then the two upper segments of the longitudinal section of the waveguide.

A method of fabricating such a modulator according to the invention comprises, for example, providing an active element or electrode, in particular on a wafer or on a coat provided on or above a wafer, and applying, preferably depositing a waveguide material to obtain the lower waveguide segment, and providing the further active element or an electrode above the lower waveguide segment, and applying, preferably depositing a waveguide material to obtain the middle waveguide segment, and applying, preferably depositing a waveguide material and subsequent structuring to obtain the upper waveguide segments and the gap therebetween.

That an element or segment or also a coat is arranged above or below another element or segment or another coat (that it is arranged, in other words, above or below another element or segment or another coat) comprises both that it is directly on or directly below the other element or segment or also the other coat, respectively and is in contact with it, for example with the upper or lower side of the other element or segment or the other coat, i.e. touches it, or also that at least one further element or segment or at least one further coat (on the upper or lower side) is located therebetween. This applies to the photodetectors and modulators according to all aspects of the invention.

According to a fourth aspect of the invention, a modulator, in particular an electro-optical modulator is provided, which comprises a longitudinal section of a waveguide comprising or being formed by five waveguide segments extending in the longitudinal direction and at least substantially parallel to one another, and two active elements comprising or consisting of at least one material whose refractive index changes as a function of a voltage and/or the presence of charge and/or an electric field, or such an active element and an electrode, wherein two lower ones of the waveguide segments are arranged below the active elements or below the active element and the electrode and are spaced apart from each other, preferably in the transverse direction, forming a gap extending therebetween, and a first middle one of the waveguide segments is arranged between the two active elements or between the active element and the electrode, and a second middle waveguide segment is arranged above the two active elements or above the active element and the electrode, and an upper waveguide segment is arranged above the second middle waveguide segment.

The upper waveguide segment preferably has an extension in the transverse direction which is less than the extension of the other waveguide segments in the transverse direction. It may be that the extension of the two lower and the two middle segments in the transverse direction is a multiple of the extension of the upper segment in this direction.

A method of fabricating such a modulator according to the invention comprises, for example, applying, preferably depositing, a waveguide material in particular on a wafer or on a coat provided on or above a wafer, and structuring to obtain the two lower waveguide segments and the gap therebetween, and providing an active element or electrode above them, and applying, preferably depositing a waveguide material to obtain the first middle waveguide segment, and providing the further active element or electrode above the first middle waveguide segment, and applying, preferably depositing, a waveguide material to obtain the second middle waveguide segment, and applying, preferably depositing a waveguide material, and preferably subsequent structuring to obtain the upper waveguide segment.

According to a fifth aspect of the invention, a modulator, in particular an electro-optical modulator, is provided, which modulator comprises a longitudinal section of a waveguide, which comprises or is formed by six waveguide segments extending in the longitudinal direction and at least substantially parallel to one another, and two active elements comprising or consisting of at least one material whose refractive index changes as a function of a voltage and/or the presence of charge and/or an electric field, or such an active element and an electrode, wherein two lower ones of the waveguide segments are arranged below the active elements or below the active element and the electrode and are spaced apart from each other, preferably in the transverse direction, forming a gap extending therebetween, and a first middle one of the waveguide segments is arranged between the two active elements or between the active element and the electrode, and a second middle waveguide segment is arranged above the two active elements or above the active element and the electrode, and the two remaining, upper waveguide segments are arranged above the second middle waveguide segment, wherein the two upper waveguide segments are spaced apart from each other, preferably in the transverse direction, forming a gap extending therebetween.

A method according to the invention for fabricating such a modulator comprises, for example, applying, preferably depositing, a waveguide material in particular on a wafer or on a coat provided on or above a wafer, and structuring to obtain the two lower waveguide segments and the gap therebetween, and providing an active element or an electrode above them, and applying, preferably depositing, a waveguide material to obtain the first middle waveguide segment, and providing the further active element or electrode above the first middle waveguide segment, and applying, preferably depositing, a waveguide material to obtain the second middle waveguide segment, and applying, preferably depositing, a waveguide material and subsequent structuring to obtain the two upper waveguide segments and the gap therebetween.

An electro-optical modulator can be used in particular for optical signal coding. An electro-optical modulator can also be designed as a ring modulator.

In the case of a modulator comprising two active elements, it is further preferred that the two active elements are spaced apart from one another and are arranged offset from one another in such a way that they lie one above the other in sections thus forming an overlap region. If a modulator comprises only one active element and one (conventional) electrode in a preferred embodiment, it can apply analogously that the active element and the electrode have been or are arranged spaced apart from one another and offset from one another in such a way that they lie one above the other in sections thus forming an overlap region.

In other words, a section of one active element then aligns or overlaps with a section of the other active element or the electrode, expediently without them touching. Preferably, at least in the region of overlapping, in other words in the overlap region, the two active elements or the active element and the electrode or at least sections thereof extend at least substantially parallel to each other.

The overlap region is particularly preferably located above or below the gap or is provided there. In particular, it is aligned therewith. The optical mode can then be guided in the slot between the two waveguide segments with high electrical field strength (slot mode). At the edges above and below the slot, part of the optical mode is outside the slot. In these regions, the optical mode can interact particularly efficiently with an active optical material.

If two gaps are present, the overlap region is located or provided above one gap and below the other. The two gaps and the overlap region or a section thereof can be aligned, which has proven to be particularly suitable. Due to the two gaps arranged one above the other, there is a particularly high proportion of the optical mode in the region between the gaps, in particular in comparison to an arrangement with only one gap, which enables a particularly efficient interaction with an electro-optical material.

According to a further development, exactly one gap formed between two waveguide segments spaced apart from one another is or has been provided above the two active elements or above the active element and the electrode. Alternatively or additionally, exactly one gap formed between two waveguide segments spaced apart from one another can be provided below the two active elements or below the active element and the electrode.

In a further particularly advantageous embodiment, the extension of the overlap region in the transverse direction corresponds to the range from 0.8 times to 1.8 times, preferably 1.0 times to 1.5 times, of the extension of the gap or at least one of the gaps in the transverse direction.

That a material changes its refractive index is to be understood in particular in that it changes its dispersion (in particular refractivity) and/or its absorption. The dispersion or refractivity is usually given by the real part and the absorption by the imaginary part of the complex refractive index. Materials whose refractive index changes as a function of a voltage and/or the presence of charge(s) and/or an electric field are understood here to be, in particular, those characterized by the Pockels effect and/or the Franz-Keldysh effect and/or the Kerr effect. In addition, materials characterized by the plasma dispersion effect are also considered to be such materials.

It has proven to be particularly suitable if at least one material of at least one of the active elements, whose refractive index changes as a function of a voltage and/or the presence of charge and/or an electric field, is graphene, possibly chemically modified graphene, and/or at least one dichalcogenide, in particular two-dimensional transition metal dichalcogenide, and/or heterostructures of two-dimensional materials and/or germanium and/or lithium niobate and/or at least one electro-optical polymer and/or silicon and/or at least one compound semiconductor, in particular at least one III-V semiconductor and/or at least one II-VI semiconductor.

Graphene has proven to be a particularly suitable material for the active element(s)—for all five aspects of the invention.

Electro-optical polymers are in particular polymers which are characterized by having a strong linear electro-optical coefficient (Pockels effect). A strong linear electro-optical coefficient is preferably understood to be one which is at least 150 pm/V, preferably at least 250 pm/V. The electro-optical coefficient is at least about five times that of lithium niobate then.

There are different chalcogenides. In the context of the present invention, transition metal dichalcogenides as two-dimensional materials, such as MoS2 or WSe2, have proven to be particularly suitable.

It should be noted that lithium niobate and electro-optical polymers are based on the electro-optical, in particular the Pockels effect, i.e. the E-field changes the refractive index (as, for example, the Pockels effect is used in the Pockels cell). In germanium, it is the Franz-Keldysh effect, i.e., the field shifts the valence and conduction band edges with respect to each other, changing the optical properties. These effects are field-based effects. For silicon or graphene, it is the charge carrier-based plasma dispersion effect, i.e., charge carriers (electrons or holes) are brought into the optical mode region (either there is a capacitor in the array which is charged or a diode with a junction which is depleted and enriched). The refractive index (real part of the index) and the absorption (imaginary part of the index, leading to free carrier absorption) change with the charge carrier concentration.

III-V semiconductors are compound semiconductors consisting of elements of the main groups III and V. II-VI semiconductors are compound semiconductors consisting of elements of main group II or Group 12 elements and elements of main group VI.

Many materials are characterized both by the fact that their refractive index changes as a function of a voltage and/or the presence of charge and/or an electric field, and by the fact that they absorb electromagnetic radiation of at least one wave length and generate, as a result of the absorption, an electrical photosignal. For graphene, for example, this is the case. Accordingly graphene is suitable for both the active elements of photodetectors and modulators. This also applies to dichalcogenides, such as two-dimensional transition metal dichalcogenides, heterostructures of two-dimensional materials, germanium, silicon, as well as compound semiconductors, in particular III-V semiconductors and/or II-VI semiconductors. Lithium niobate, for example, is generally only suitable for modulators. Since it is transparent, it does not meet the absorbing property and therefore is not considered for photodetectors.

A material which absorbs electromagnetic radiation of at least one wavelength and generates an electrical photosignal as a result of the absorption and/or whose refractive index changes as a function of a voltage and/or the presence of charge and/or an electric field can also be referred to as an electro-optically active material. In other words, the active element or elements comprise at least one electro-optically active material or consist of at least one electro-optically active material.

It may be that the active elements or at least one of the active elements is provided in the form of a film. A film is preferably characterized in a manner known per se by a significantly greater lateral extension than thickness. The at least one active element may further be characterized by a square or rectangular cross-section.

The active element or at least one active element may further comprise or be formed of one or more layers or coats of at least one material whose refractive index changes and/or which absorbs. In particular, it may be provided that the active element or at least one active element is formed as a film comprising several layers or coats of one or also different materials.

Films of graphene, possibly chemically modified graphene, or dichalcogenide-graphene heterostructures consisting of at least one layer of graphene and at least one layer of a dichalcogenide or arrangements of at least one layer of boron nitride and at least one layer of graphene have proven to be particularly suitable.

Active elements can, for example, also comprise or be provided by one or more silicon coats. In this case, in particular, one or more active elements or sections thereof may form a waveguide (section).

The active element(s) may further be doped or have doped sections or regions, for example be p-doped and/or n-doped or comprise corresponding sections or regions. It may also be that a p-doped region and an n-doped region and a preferably intermediate undoped region are present or provided. This is also referred to as a pinjunction, where the i stands for intrinsic, i.e. undoped.

In the context of the fabrication of the active element or the respective active element, the same processes can be used or have been used which were explained above in connection with the gate electrodes.

This also includes transfer processes. Meaning in particular that the respective element is/are/were not produced monolithically, for example on a coat, but is/are/were produced separately and then transferred, in other words is/are/were transferred. A transfer process for graphene is described, for example, in the papers “Large-Area Synthesis of High-Quality and Uniform Graphene Films on Copper Foils” from Li et al., Science 324, 1312, (2009) and “Roll-to-roll production of 30-inch graphene films for transparent electrodes” from Bae et al, Nature Nanotech 5, 574-578 (2010) or for LiNbO in the paper “Integrated lithium niobate electro-optic modulators operating at CMOS-compatible voltages”, Nature volume 562, pages 101104 (2018 ) or, inter alia, for GaAs in the paper “Transfer print techniques for heterogeneous integration of photonic components”, Progress in Quantum Electronics, Volume 52, March 2017, Pages 1-17. One of these processes can also be used in the context of the present invention to obtain one or more graphene or LiNbO or GaAs coats/films. A transfer process may be followed by structuring.

Above, possibly on at least one of the active elements, a passivation coat and/or a cladding may further be provided. A cladding is particularly suitable or designed to make the index contrast somewhat lower, so that roughnesses on the sidewalls do not have quite as strong an effect; usually the losses go back into the waveguide(s). A passivation coat preferably serves the purpose of protecting the device or circuit from environmental influences, in particular water. A passivation coat can, for example, consist of a dielectric material. Aluminium oxide (AL₂O₃) and silicon dioxide (SiO₂) have proven to be particularly suitable.

An upper, final passivation coat expediently has openings or interruptions to underlying contacts to enable electrical connection. Openings or interruptions in a passivation coat can be or have been obtained, for example, by lithography and/or etching, in particular reactive ion etching.

The respective active element(s) can be connected to a contact or contact element on one side or also on opposite sides in each case. The contacts or contact elements can be in contact with interconnection elements, in particular VIAs. Via the interconnection elements, for example, a connection to one or more integrated electronic components from the front-end-of-line of a chip or wafer can be achieved. The term “connected” is intended to mean connected in an electrically conductive manner.

It should be noted that in particular in the case of a detector with only one active element it may be provided that this active element is in contact with two contacts or contact elements, preferably on opposite sides, and in the case of a modulator with two active elements or one active element and one electrode it applies that these are each in contact with a contact or contact element. This is preferably the case at those end regions or ends which face away from the region in which they overlap or overlap in sections.

The active element or at least one of the active elements is or are expediently arranged relative to the longitudinal section of the waveguide in such a way that it is exposed, at least in sections, to the evanescent field of electromagnetic radiation guided therein. Preferably, at least one active element has been or is arranged at a distance less than or equal to 50 nm, more preferably less than or equal to 30 nm, from the longitudinal section of the waveguide, for example at a distance of 10 nm.

The active element or at least one of the active elements is further preferably characterized by an extension in longitudinal direction in the range of 5 to 500 micrometers.

It may also be that the active element or at least one of the active elements extends at least in sections on and/or within the longitudinal section of the waveguide, in the latter case for example between two segments thereof.

In a further advantageous embodiment, it is provided that the active element or at least one of the active elements is arranged on or above the waveguide in a region of the longitudinal section of the waveguide which is at least substantially trapezoidal in cross-section and preferably follows the trapezoidal shape. Alternatively or additionally, it may be provided that the active element or at least one of the active elements is arranged in an at least substantially trapezoidal region of a planarization coat on or above the planarization coat, as viewed in transverse section, and preferably follows the trapezoidal shape.

In waveguides, part of the electromagnetic radiation, in particular the light, is evanescently guided outside the waveguide. The interface of the waveguide is dielectric and accordingly the intensity distribution is described by the boundary conditions according to Maxwell with an exponential decay. If an electro-optically active material, for example graphene, is placed on or near the waveguide in the evanescent field, photons can interact with the material, in particular graphene.

There are four effects in graphene that lead to photocurrent. One is the bolometric effect, according to which the absorbed energy increases the resistance of the graphene and reduces an applied DC current. The change of the DC current is then the photosignal. Another effect is the photoconductivity. Here, absorbed photons cause the charge carrier concentration to increase and the additional charge carriers reduce the resistance of the graphene because of the proportionality of the resistance to the charge carrier concentration. An applied DC current increases and the change is the photosignal. There also is a thermoelectric effect, according to which a thermoelectric voltage results from a pn-junction and a temperature gradient at this junction due to different Seebeck coefficients for the p and n region. The temperature gradient results from the energy of the absorbed optical signal. This thermoelectric voltage is the signal then. The fourth effect is due to the fact that at a pn-junction the excited electron-hole pairs are separated. The resulting photocurrent is the signal.

In case of a modulator, as explained above, an electrical control electrode and an active element, suitably insulated for this purpose, can be provided comprising or consisting of at least one material whose refractive index changes as a function of a voltage or charges or an electric field, in particular graphene, or the electrode can also be made of a corresponding material, in particular graphene, so that in operation two active elements are then together in the evanescent field and perform the electro-optical function. Graphene, for example, can change its optical properties by a control voltage. In the particularly advantageous case of a graphene-dielectric-graphene arrangement, a capacitance is created and the two films of graphene influence each other. A voltage charges the capacitance consisting of the graphene electrodes forming two active elements and the electrons occupy states in the graphene. This results in a shift of the Fermi energy (energy of the last occupied state in the crystal) to higher energies (or to lower ones due to symmetry). When the Fermi energy reaches half the energy of the photons, they can no longer be absorbed because the free states required for the absorption process are already occupied at the correct energy. Consequently, in this state, the graphene is transparent because absorption is forbidden. By changing the voltage, the graphene is switched back and forth between absorbing and transparent. A continuously shining laser beam is modulated in its intensity and can thus be used for information transmission. Likewise, the real part of the refractive index changes with the control voltage. By changing the voltage, the phase position of a laser can be modulated via the changing refractive index and thus phase modulation can be achieved. Preferably, the phase modulation is operated in a range where all states are occupied up to above half the photon energy, so that the graphene is transparent and the real part of the refractive index shifts significantly and the change of the absorption plays a minor role.

Also in connection with both the photodetectors according to the first and second aspect and the modulators according to the third, fourth and fifth aspects of the invention, the following may further apply.

A waveguide or a longitudinal section thereof is in particular an element or component, that guides an electromagnetic wave, in particular light. In order to guide the wave, a wavelength-dependent cross-section of a material which is optically transparent for at least this wavelength and which is distinguished from an adjacent material, which is also transparent for this wavelength, by a refractive index contrast is expediently provided. If the refractive index of the surrounding material is lower, the light is guided in the region of higher refractive index. For the particular case of a slit mode, two regions of high refractive index are separated from a region of low refractive index that is narrow with respect to the wavelength, and the light is guided in the region of low refractive index. To achieve low losses due to scattering, a low sidewall roughness is advantageous.

In general, one or more waveguides is/are provided, for example, on a chip or a wafer. Part of a photodetector or modulator according to the invention will be usually only a longitudinal section of such a photodetector or modulator, expediently a longitudinal section which extends below an active element of the latter. Of course, it is not excluded that a waveguide over its entire longitudinal extension is considered to be part of a photodetector or modulator according to the invention. In other words, in addition to the longitudinal section of a waveguide extending in particular below an active element, such a waveguide can also comprise the remaining part of the latter.

As far as the dimensions of waveguide are concerned, the following may apply, for example. The thickness is preferably in the range from 150 nanometers to 10 micrometers. In particular, the width and length of the waveguides may be in the range of 100 nanometers and 10 micrometers.

A waveguide may, for example, be formed as a strip waveguide, which is characterized, for example, by a rectangular or square cross-section, which then also applies to a longitudinal section of such a waveguide. A waveguide may alternatively or additionally be formed as a ridge waveguide with a T-shaped cross-section. Further alternatively or additionally, it is possible that a waveguide is given by a slot waveguide.

A waveguide or longitudinal section of such a waveguide can comprise several sections or segments in cross-section and can be formed in several parts, for example comprising or consisting of a first, for example lower or left, and a second, for example upper or right, segment. It may be that one or more waveguide segments are characterized by a rectangular or square cross-section. It is also possible that one or more segments of a waveguide are characterized, at least in sections, by a tapering cross-section and/or, at least in sections, by a widening cross-section.

If a waveguide comprises or consists of two or more segments, these can be adjacent to or merge into one another or can also be spaced apart from one another, for example forming at least one gap or slot.

The longitudinal section of the waveguide comprises—both in the case of the above-mentioned photodetectors according to the first and second aspects and the above-mentioned modulators according to the third, fourth and fifth aspects of the invention—in a particularly useful embodiment at least one material which is transparent to electromagnetic radiation of a wavelength of 850 nm and/or 1310 nm and/or 1550 nm or consists of such a material. Particularly preferably, it is transparent to electromagnetic radiation in the wavelength range from 800 nm to 900 nm and/or from 1260 nm to 1360 nm (so-called original band or O-band for short) and/or 1360 nm to 1460 nm (so-called extend band or E-band for short) and/or 1460 nm to 1530 nm (so-called short band or S-band for short) and/or from 1530 nm to 1565 nm (so-called conventional band or C-band for short) and/or 1565 nm to 1625 nm (so-called long band or L-band for short). These bands are known from the field of communication engineering.

As materials for the longitudinal section of the waveguide, for example, the following have proven to be particularly suitable: titanium dioxide and/or aluminium nitride and/or tantalum pentoxide and/or silicon nitride and/or aluminium oxide and/or silicon oxynitride and/or lithium niobate and/or silicon, in particular polysilicon, and/or indium phosphite and/or gallium arsenide and/or indium gallium arsenide and/or aluminium gallium arsenide and/or at least one dichalcogenide, in particular two-dimensional transition metal dichalcogenide, and/or chalcogenide glass and/or heterostructures made of two-dimensional materials and/or resins or resin-containing materials, in particular SU8, and/or polymers or polymer-containing materials, in particular OrmoClad and/or OrmoCore. In this regard, the longitudinal section of the waveguide may comprise one or more of these materials, or may comprise one of these materials or a combination of two or more of these materials. This may apply in each case to only one or more or possibly all of the waveguide segments.

If the longitudinal section of the waveguide comprises a plurality of waveguide segments, these may all comprise the same material or materials or consist of the same material or materials. However, it is of course also possible for two or more segments to differ in terms of their material or materials. For example, it may be that at least one waveguide segment is characterized by a refractive index which is greater than the refractive index of at least one other waveguide segment. For example, if several waveguide segments are sandwiched or stacked, the outer segments may have a lower refractive index. In this case, the light is concentrated in the center of the waveguide arrangement. Purely exemplary materials are an upper and lower segment of aluminium oxide with a middle segment of titanium oxide therebetween.

A higher refractive index—compared to the remaining segments—has also proven to be advantageous for a waveguide segment located between two active elements, since the light is then focused in the region of the active elements.

Different materials of the segments of a waveguide (section) can also be advantageous for the reason that they are characterized by different etch rates. This can offer advantages in the fabrication, for example for required structuring.

The fabrication of the longitudinal section of the waveguide may include or may have included that a waveguide material is or has been applied, in particular deposited or spun on or transferred, and then preferably a structuring of the applied waveguide material is or has been carried out, in particular by means of lithography and/or reactive ion etching (RIE). For example, the same deposition processes mentioned above in connection with the gate electrodes may be used.

The waveguide or longitudinal section of this can be formed in one or more parts. It can be formed from several waveguide segments or comprise several waveguide segments, in particular when viewed in cross-section. These can be spaced apart from each other or lie directly against each other and be in contact with each other, for example because one segment has been fabricated directly on another segment, such as by application, for example by deposition, of material.

The longitudinal section of the waveguide further preferably consists of at least one material whose refractive index differs from the refractive index of a material surrounding it, or it comprises at least one such material.

If the waveguide or longitudinal section of the waveguide is one that comprises two or more segments, at least two of which are spaced apart from one another to form a gap, it can be provided in an advantageous embodiment that the gap is or has been filled with at least one dielectric material whose refractive index is lower than the refractive index of the material of the waveguide segments defining the gap.

The longitudinal section of the waveguide may be surrounded on one or more sides, for example, by a planarization coat. Purely exemplary pairs of refractive indices in such a case are 3.4 (Si) for the longitudinal section of the waveguide and 1.5 (SiO₂) for the planarization coat or, in the case of dielectrics, 2.4 (TiO₂) for the longitudinal section of the waveguide and 1.5 (SiO₂) for the planarization coat or 2 (SiN) for the longitudinal section of the waveguide and the 1.47 for the planarization coat.

It is particularly preferred that the refractive index of the longitudinal section of the waveguide is at least 20%, preferably at least 30% greater than the refractive index of the surrounding material.

The longitudinal section of the waveguide may further be disposed on or above a planarization coat.

Preferably, the planarization coat is then characterized, at least in sections, by a roughness in the range from 1.0 nm RMS to 0.1 nm RMS, in particular 0.6 nm RMS to 0.1 nm RMS, preferably 0.4 nm RMS to 0.1 nm RMS, on the side on which the longitudinal section of the waveguide is arranged thereon. Here and in the following the abbreviation nm stands in a well-known manner for nanometer (10⁻⁹ m)

Alternatively or additionally, the longitudinal section of the waveguide can be embedded at least in sections in a planarization coat, and the active element or—in the case of a modulator with two such elements—one of the active elements is arranged on the planarization coat. In this case, it can preferably apply that the planarization coat is characterized, at least in sections, by a roughness in the range of 1.0 nm RMS to 0.1 nm RMS, in particular 0.6 nm RMS to 0.1 nm RMS, preferably 0.4 nm RMS to 0.1 nm RMS, on the side on which the active element is arranged thereon.

If the longitudinal section of the waveguide is both disposed on top of a planarization coat and embedded in a planarization coat, two planarization coats are present.

To achieve suitable roughness, for example, chemical-mechanical polishing and/or resist planarization can be or has been performed.

In chemical-mechanical polishing, an object to be polished is usually polished by a rotating movement between grinding pads. The polishing is performed chemically on the one hand and physically on the other hand by means of an abrasive paste. By combining the chemical and physical action, smooth surfaces can be obtained on a sub-nm scale.

In particular, resist planarization includes a single or repeated spin-on-glass deposition and subsequent etching, preferably reactive ion etching (RIE). If a surface, such as a SiO₂ surface, which has height differences, is to be planarized, this can be done by spin-on-glass deposition and etching. The spin-on-glass coat partially compensates for the height differences, i.e. valleys of the topology have a higher coat thickness after spin-on-glass coating than adjacent elevations. The etch rate of spin-on-glass and, for example, SiO₂ is similar or the same in an adapted RIE process. Adapted here means in particular that the pressure, the gas flow, the composition of the gas mixture and the power are selected accordingly. If the entire spin-on-glass coat is etched by RIE after spin-on-glass coating, the height difference has been reduced due to the planarizing effect of the spin-on-glass coat. The height difference can be further reduced by repetition. The consumed SiO₂ coat thickness must be taken into account when depositing the SiO₂ coat, so that the desired SiO₂ coat thickness is achieved after completing the final etching step. It should be emphasized that resist planarization is not limited to SiO₂, but can also be considered for other materials. It is convenient if an etch rate of the material can be achieved that is similar to, or at least substantially the same as, that of spin-on-glass. For SiO₂ and spin-on-glass, this condition is met. It should be noted that, for example, materials whose etch rate differs from that of spin-on-glass by a factor of 2 are also possible, in which case several passes are generally necessary. Hydrogen silsesquioxane and/or a polymer, for example, can be applied as a liquid material, in particular spun on. It vitrifies during subsequent annealing, which is why it is also referred to as spin-on glass. Hydrogen silsesquioxane (HSQ) is a class of inorganic compounds with the formula [HSiO_{3/2}]ₙ.

Chemical-mechanical polishing and/or resist planarization can in particular be or have been carried out in such a way that a roughness in the range from 1.0 nm RMS to 0.1 nm RMS, in particular 0.6 nm RMS to 0.1 nm RMS, preferably 0.4 nm RMS to 0.1 nm RMS is or has been obtained.

Roughnesses in the above ranges have proven to be particularly suitable. They are particularly advantageous for avoiding stress and distortion in overlying layers. In this context, it is also referred to the paper “Identifying suitable substrates for high-quality graphene-based heterostructures” by L. Banszerus et al, 2D Mater. vol. 4, no. 2, 025030, 2017.

It should be noted that in case the dielectric layer, which in the photodetector according to the first aspect of the invention may be provided in particular between the gate electrodes and the active elements, is characterized by a roughness in the above-mentioned range on its upper side, it may be or may have been obtained in the same way, for example by CMP and/or resist planarization.

Atomic force microscopy (AFM) can be used as a measuring method for determining the roughness, in particular as described in EN ISO 25178 standard. Atomic force microscopy is discussed in particular in Part 6 (EN ISO 25178-6:2010-01) of this standard, which deals with measurement methods for roughness determination.

Furthermore, it can be provided that the planarization coat and/or a further planarization coat, if present, comprises one or more cover layers which are preferably provided on a surface subjected to a planarization treatment and which can be, for example, dichalcogenide layers or dichalcogenide heterostructures or also boron nitride layers. These materials are preferably deposited or transferred without the need for further chemical-mechanical polishing or further resist planarization, although the possibility of this being carried out again is not excluded.

It can also be provided that the respective planarization coat is obtained by deposition or is a coat obtained by deposition. In principle, the same processes can be or have been used for the planarization coat that were mentioned above in connection with the gate electrodes (e.g. CVD, PVD, atomic layer deposition, transfer). This and the following explained for the planarization coat can also apply to the dielectric layer, if present.

A coat can comprise only exactly one or also several layers. It may consist of only one material or may comprise several materials. For example, a coat may comprise two or more layers of two or more different materials. Of course, it is also possible for a coat to have multiple layers, but all made of the same material. A coat with more than one layer can in particular be obtained or be present because several layers, for example several atomic layers, are provided for its fabrication, for example are or have been deposited.

The planarization coat or each planarization coat may further comprise or consist of spin-on-glass and/or at least one polymer and/or at least one oxide, in particular silicon dioxide, and/or at least one nitride. Spin-on-glass is generally a liquid substance by which wafers can be coated by spin-on. After spin-on, a coat is formed on the wafer, the thickness of which depends on the surface topology. Deepenings are thus partially smoothed out and the spin-on-glass coating has a planarizing effect. Spin-on-glass is usually heated after deposition and thus becomes a glass-like coat.

In particular, a modulator may further be provided to comprise a diode or capacitor. For example, it may be an integrated III-V semiconductor modulator as described in the paper “Heterogeneously integrated III-V/Si MOS capacitor Mach-Zehnder modulator” from Hiaki, Nature Photonics volume 11, pages 482-485 (2017).

If a diode is or has been provided, it may comprise, for example, a plurality of coats of different compositions of, for example, InGaAsP, in particular to create a pn-junction and two contact regions.

Subject of the invention is also a semiconductor apparatus comprising a chip and at least one, preferably a plurality of photodetectors and/or modulators according to the present invention, wherein the one or more photodetector(s) are preferably arranged on the chip or on a coat arranged on or above the chip.

Finally, the invention relates to a semiconductor device comprising a wafer and at least one, preferably a plurality of photodetectors and/or modulators according to the present invention, wherein the one or more photodetectors and/or modulators are preferably arranged on the wafer or on a coat arranged on or above the wafer.

The photodetector(s) and/or modulator(s) may, for example, be part of a photonic platform fabricated on the chip or wafer or bonded to the chip or wafer.

Bonded means in particular that the photodetector(s) and/or modulator(s) is/are not fabricated on or above the chip or wafer but separately therefrom and are bonded to the chip or wafer after fabrication—possibly also as part of a larger unit—for example by using a suitable intercoat.

If a chip or wafer is viewed in cross-section, its vertical structure can be divided into different sub-regions. The lowest part is the front-end-of-line, or FEOL for short, which usually comprises one or more integrated electronic components. The integrated electronic component(s) may be, for example, transistors and/or capacitors and/or resistors. Above the front-end-of-line is the back-end-of-line, or BEOL for short, in which there are usually various metal planes by means of which the integrated electronic components of the FEOL are interconnected.

A wafer comprises a plurality of regions which, following dicing/dividing/fragmenting, each form a chip or die. These regions are also referred to as chip or die regions. Each chip region of the wafer preferably comprises a section or partial section of the in particular single-piece semiconductor substrate of the wafer. Preferably, each chip region further comprises one or more integrated electronic components extending in and/or on the corresponding region of the semiconductor substrate—in particular in the FEOL when viewed in cross-section. It should be emphasized that the chip regions do not represent individual chips, i.e. the wafer does not comprise individual chips.

Both for a semiconductor apparatus according to the invention and for a semiconductor device according to the invention it can be valid that it comprises a plurality of identically designed photodetectors according to the invention and/or a plurality of identically designed modulators according to the invention or also a plurality of differently designed photodetectors according to the invention and/or a plurality of differently designed modulators according to the invention. There may also be some identical photodetectors and/or modulators and additionally one or more differently designed photodetectors and/or modulators.

With regard to embodiments of the invention, reference is also made to the sub-claims as well as to the following description of several example embodiments with reference to the accompanying drawing.

In the drawing shows:

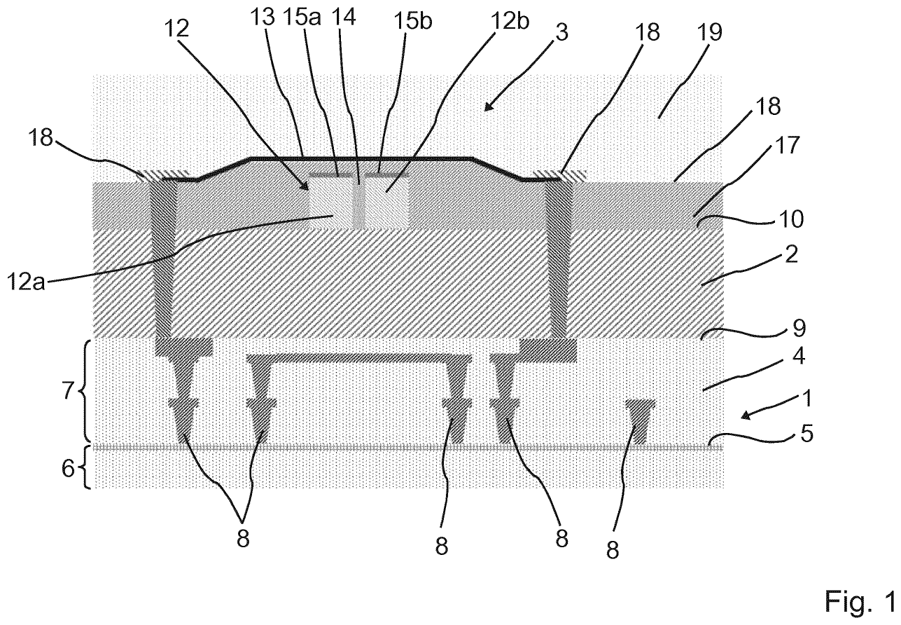

FIG. 1 a partial section through a semiconductor device comprising an embodiment of a photodetector according to the first aspect of the invention;

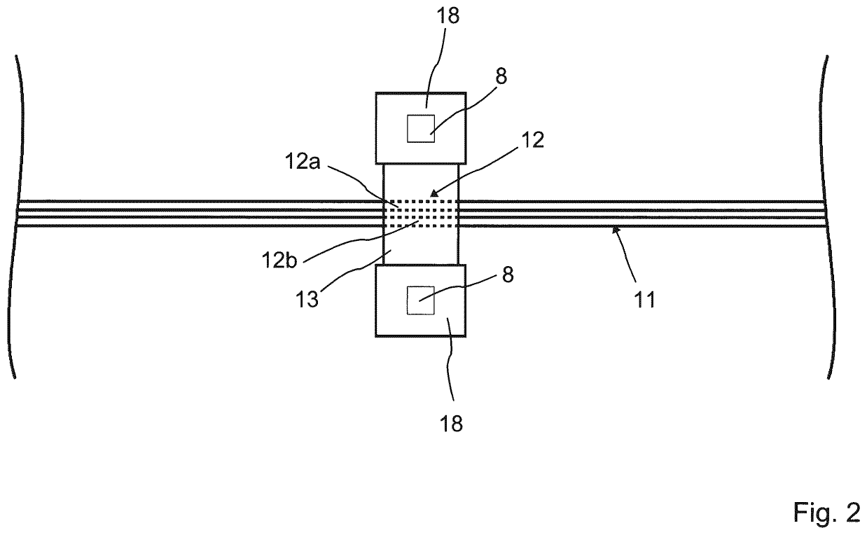

FIG. 2 a top view of the photodetector of FIG. 1;

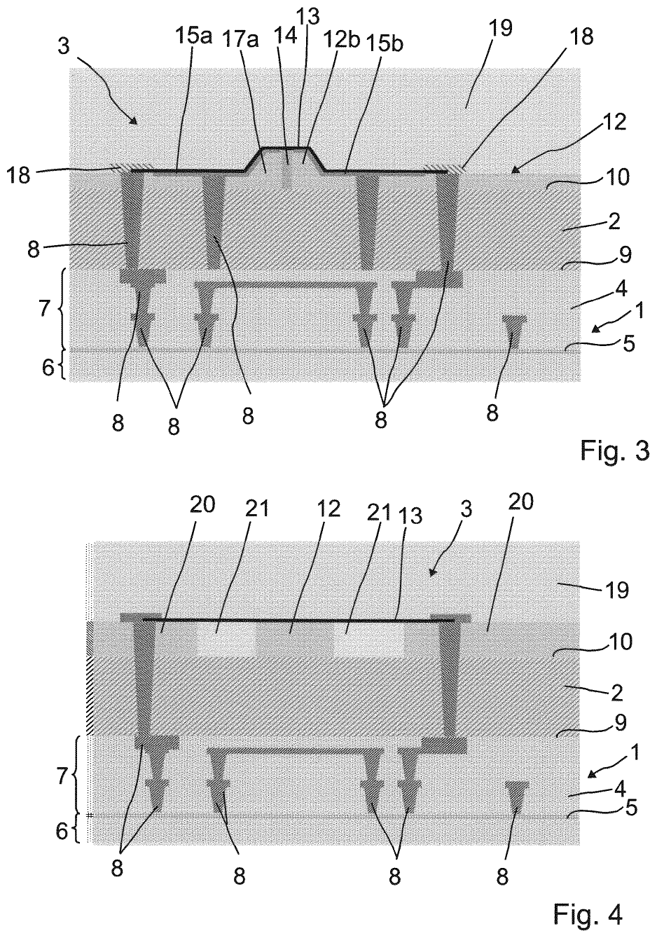

FIG. 3 a partial section through a semiconductor device with a further embodiment of a photodetector according to the first aspect of the invention;

FIG. 4 a partial section through a semiconductor device with an embodiment of a photodetector according to the second aspect of the invention;

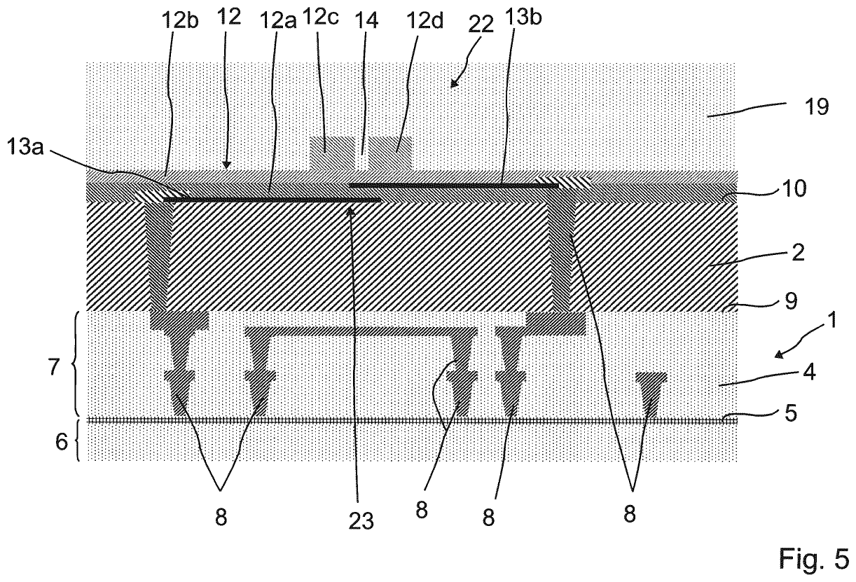

FIG. 5 a partial section through a semiconductor device with an embodiment of an electro-optical modulator according to the third aspect of the invention;

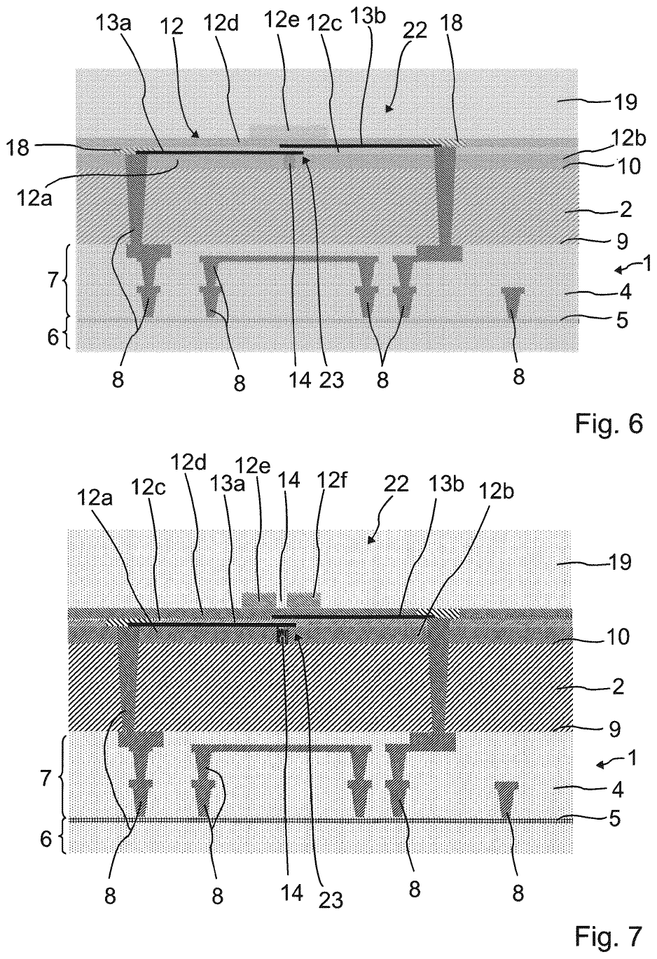

FIG. 6 a partial section through a semiconductor device with an embodiment of an electro-optical modulator according to the fourth aspect of the invention;

FIG. 7 a partial section through a semiconductor device with an embodiment of an electro-optical modulator according to the fifth aspect of the invention; and

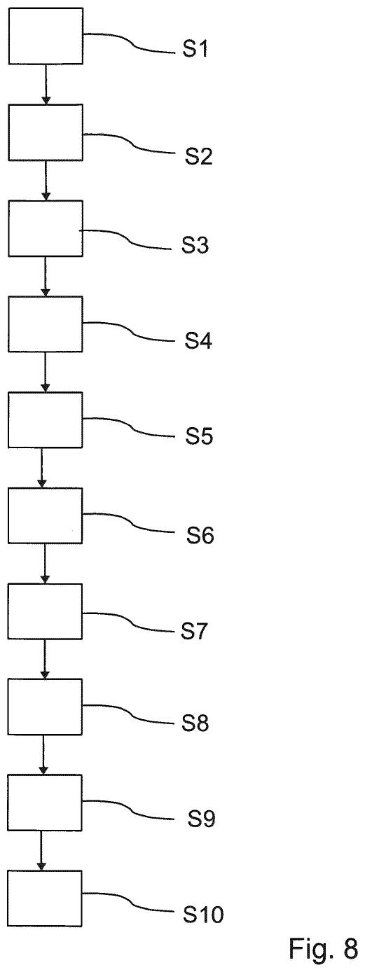

FIG. 8 the steps of the method of fabricating the device according to FIG. 1.

All figures show purely schematic representations. In the figures, the same components or elements are given the same reference signs.

FIG. 1 shows a partial section through an embodiment of a semiconductor device according to the invention.

It comprises a wafer 1, a planarization coat 2 fabricated on the wafer 1 and a plurality of photodetectors 3 fabricated on the planarization coat 2. In the partial section according to FIG. 1, only one of the photodetectors 3 is shown as exemplarily.

The wafer 1 comprises a single-piece silicon substrate 4 and a plurality of integrated electronic components 5, which, in the example shown, extend in the semiconductor substrate 4. The integrated electronic components 5, which may in particular be transistors and/or resistors and/or capacitors, are indicated in the schematic FIG. 1 only simplified by a line with hatching provided with the reference sign 5. In a corresponding position in the substrate 4, a large number of integrated electronic components 5 are found in a sufficiently known manner. These can also be components of processors, such as CPUs and/or GPUs, or form such components in a likewise known manner.

The wafer 1 has a front-end-of-line (FEOL for short) 6, in which the plurality of integrated electronic components 5 are arranged, and a back-end-of-line (BEOL for short) 7 lying thereabove, in which or via which the integrated electronic components 5 of the front-end-of-line 6 are interconnected by means of different metal planes. The integrated electronic components 5 in the FEOL 6 and the associated interconnection in the BEOL 7 form integrated circuits of the wafer 1 in a manner that is sufficiently pre-known. A FEOL 6 is also sometimes referred to as transistor front-end and a BEOL 7 as a metal back-end. The metal planes comprise a plurality of interconnection elements 8, which in the present case are given by so-called VIAs, which is the abbreviation for Vertical Interconnect Access. The VIAs 8 consist of metal, for example copper, aluminium or tungsten.

The planarization coat is fabricated on the upper side 9 of the wafer 1 facing away from the front-end-of-line 6 and consists of a dielectric material. In the present case, the planarization coat 2 consists of silicon dioxide (SiO₂), although this is to be understood as exemplary and other materials may also be used.

In the embodiment shown, the planarization coat 2 is a coat obtained by deposition of the corresponding coating material, in this case SiO₂, on the upper side 9 of the wafer 1 facing away from the front-end-of-line 6 and subsequent planarization treatment of the deposited material on the upper side 10 facing away from the wafer. Due to the treatment on its upper side 10 facing away from the wafer 1, the planarization coat 2 is presently characterized by a roughness of 0.2 nm RMS, wherein this is to be understood as exemplary.

In the example shown, the planarization coat 2 extends over the entire upper side 9 of the wafer 1. The material of the planarization coat 2 has been deposited over the entire upper side 9 of the wafer 1. This is therefore characterized by a diameter which at least substantially corresponds to that of the wafer 1.

The photodetectors 3 fabricated on the planarization coat 2 are embodiments of a photodetector 3 according to the first aspect of the invention. In the embodiment, these are all identical in construction, although this is not to be understood restrictively.

In the following, the design of the detectors 3 and also their fabrication will be described by way of example on the basis of the one detector 3 shown in FIG. 1. Also, with regard to the embodiments of further detectors and modulators described further below (cf. FIGS. 3 to 6), the design is explained on the basis of the one example shown in the partial sections.

The (respective) photodetector 3 comprises a longitudinal section 12 of one of the waveguides 11, namely that longitudinal section which is overlapped by an active element 13 of the photodetector 3. In FIG. 2, which shows the active element 13 and the underlying waveguide 11 in purely schematic top view, the longitudinal section 12 of the waveguide covered here by the active element 13 is shown with dashed lines.

Dielectrics, preferably titanium dioxide, which was also used in the embodiment shown, are particularly suitable as waveguide materials. Alternatively or additionally, one or more waveguides 11 of aluminium nitride and/or tantalum pentoxide and/or silicon nitride and/or aluminium oxide and/or silicon oxynitride and/or lithium niobate or also of semiconductors such as silicon, indium phosphide, gallium arsenide, indium gallium arsenide, aluminium gallium arsenide or dichalcogenides or chalcogenide glass or polymers such as SU8 or Ormo-Clad and/or OrmoCore can be provided.

The longitudinal section 12 of the waveguide is formed here by two waveguide segments 12a, 12b extending in longitudinal direction and at least substantially parallel to each other and spaced apart from each other in the transverse direction (from left to right or vice versa in the figure) to form a gap 14 extending therebetween. It accordingly is a slot waveguide. By means of such a waveguide 11, the optical mode is guided in the gap 14 during operation. In the example shown, the two waveguide segments are characterized by a rectangular cross-section. The gap 14 can be filled with SiO₂, for example.

The two waveguide segments 12a, 12b are each in contact with a silicon gate electrode 15a, 15b at least on one side, in this case on their side facing the active element 13. The gate electrodes 15a, 15b are formed by a silicon coat or silicon coating fabricated on the respective waveguide segment 12a, 12b.

The active element 13 comprises at least one material or consists of at least one material which absorbs electromagnetic radiation of at least one wavelength and generates an electrical photosignal as a result of the absorption. In the example shown, it is given by a graphene film 13. Graphene may also change its refractive index (refractivity and/or absorption) as a function of a voltage and/or charge and/or an electric field. It should be emphasized that it is also possible that the active element 13 is given by a film comprising or consisting of at least one other or further electro-optically active material, for example a film comprising or consisting of a dichalcogenide-graphene heterostructure consisting of at least one layer of graphene and at least one layer of a dichalcogenide, or by a film comprising at least one layer of boron nitride and at least one layer of graphene.

As can be seen from FIG. 1, the graphene film 13 is arranged on the upper side 16, facing away from the wafer 1, of a further planarization coat 17 in which the waveguide 11 and thus its longitudinal section 12 is embedded. The further planarization coat 17 consists of the same material as the planarization coat 2 and is characterized at its upper side 16 by the same roughness as the upper side 10 of the planarization coat 2. However, this is to be understood only exemplarily and not restrictively.

By means of the gate electrodes 15a, 15b provided on the waveguide segments 12a, 12b, a pnjunction can be realized in the graphene film 13 in the region extending above the gap 14 and thus in the region of an optical mode guided in operation in the gap 14 of the waveguide 11. A pnjunction can be used to separate electron-hole pairs generated by absorption to produce a photocurrent. Likewise, the thermoelectric effect can be exploited in graphene, where Seebeck coefficients of opposite sign are created in the p and n regions, resulting in a thermoelectric voltage when heated by the absorbed energy (the photons).

It should be noted that the connection of the gate electrodes 15a, 15b for power supply, which is not shown further, can be located, for example, laterally next to the VIAs 8.

The photodetector 3, specifically its graphene film 13, is electrically conductively connected to at least one of the integrated electronic components 5 of the front-end-of-line 6 of the wafer 1. As can be seen in the schematic sectional view according to FIG. 1, the connection is realized by the VIAs 8 of the back-end-of-line 7 of the wafer 1 as well as further VIAs 8, which extend through the planarization coat 2 and any further coats or elements present thereon, in this case the further planarization coat 17.

In concrete terms, the graphene film 13 is electrically conductively connected at opposite end regions via contacts or contact elements 18 with the upper end of VIAs 8, which extend through the further planarization coat 17 and planarization coat 2 to the back-end-of-line 7 of wafer 1. In the top view of FIG. 2, the VIAs 8 in connection with the contact elements 18, which VIAs 8 lie below the contact elements 18, are indicated with a thin line.

In the example shown, a passivation coat 19 is provided on the graphene films 13, which comprises or consists of aluminium oxide (AL₂O₃) and/or silicon dioxide (SiO₂).

A photodetector 3, as shown in FIG. 1 and in FIGS. 3 and 4, which will be explained below, can be used in a manner known per se, in particular for signal conversion back from the optical to the electronic world.

To obtain the semiconductor device shown in FIG. 1, in a first step S1 (cf. FIG. 8) the wafer 1 is provided with the integrated circuits comprising the integrated electronic components 5 and the metallization including the VIAs 8. The wafer 1 may be any wafer 1 of conventional type obtained by a previously known fabricating process.

In a second step S2, the planarization coat 2 is fabricated on the back-end-of-line 7 of the wafer 1. For this purpose, a coating material, in this case silicon dioxide (SiO₂), is applied, which can be done, for example, by chemical vapor deposition, such as low-pressure chemical vapor deposition or plasma-enhanced chemical vapor deposition, or physical vapor deposition or also by spinning on spin-on glass. In the present case, PECVD is used. After the coating material has been deposited, the upper side of the coating obtained is subjected to a planarization treatment (step S3), in this case resist planarization, whereby an upper side 10 having a roughness of 0.2 nm RMS is obtained.

The resist planarization includes a single or repeated spin-on glass spinning on and subsequent etching, presently reactive ion etching (RIE). The spin-on-glass coat partially compensates for height differences, i.e., valleys of the topology have a higher coat thickness after spin-on-glass coating than adjacent elevations. If the entire spin-on-glass coat is etched after spin-on-glass coating, for example by RIE, the height difference has been reduced due to the planarizing effect of the spin-on-glass coat. By repetition, the height difference can be further reduced until the desired roughness is obtained. It should be noted that an upper side 10 of the planarization coat 2 corresponding to low roughness can alternatively be obtained, for example, by means of chemical mechanical polishing (CMP).

In a next step S4, which represents the first step in the fabrication of the detector 3, the (respective) waveguide 11 with the gate electrodes 15a, 15b is fabricated. For this purpose, waveguide material, presently titanium dioxide (TiO₂), is deposited, in particular over the entire upper side 10 of the obtained planarization coat 2. The deposition can be carried out by PVD or CVD, in particular PECVD or LPCVD, or by spinning on, just as for the planarization coat. Atomic layer deposition (ALD) can also be carried out or a transfer print process. In analogy to the planarization coat 2, LPCVD is used.

Subsequently, the coating material for the gate electrodes 15a, 15b, gate electrode material, in this case silicon, is deposited, for example by means of PVD or CVD processes and preferably also in a two-dimensional manner.

Lithography and structuring, in particular by means of reactive ion etching (RIE), are carried out in order to obtain the individual waveguides 11 with the individual waveguide segments 12a, 12b with the respective gap 14 lying therebetween and the individual gate electrodes 15a, 15b.

In a next step S5, the further planarization coat 17 is fabricated on the waveguides 11 with gate electrodes 15a, 15b provided thereon and the upper side 10 of the planarization coat 2. This is obtained in a completely analogous manner to the planarization coat 2 by deposition by means of PECVD and resist planarization. During or due to the material deposition, the gap 14 is also filled with SiO₂. As a result of the resist planarization, the cross-section of the further planarization coat 17 above the waveguide 11 is trapezoidal (see FIG. 1).

Also, with regard to the further planarization coat 17, it applies that alternatively to LPCVD and CMP, other of the above-mentioned processes can be used and another planarization treatment, such as CMP, and/or further planarization is possible, as described above for the planarization coat 2.

The planarization coat 2 and further planarization coat 17 may comprise one or more cover layers which are preferably provided on the surface subjected to planarization treatment and which may be, for example, dichalcogenide layers or dichalcogenide heterostructures or also boron nitride layers. These materials are preferably deposited or transferred without the need for further chemical-mechanical polishing or further resist planarization, although this is not excluded.

For the sake of completeness, it should be noted that in the event that a semiconductor device according to the invention is also to have regions without a further planarization coat 17, for example also regions in which the structure corresponds to that according to FIGS. 3 to 6, the further planarization coat 17 (and any coats located thereon) is subsequently partially removed again, in particular by lithography and etching.

In step S6, the VIAs 8 are fabricated through the planarization coat 2 and the further planarization coat 17. In principle, this can be done in any way known from the prior art. In particular, the regions in which they are to extend are first defined, preferably by lithography, and dry-chemically etched by means of RIE. Then metallization is carried out and the metallized surface is structured, for example by means of CMP (Damascene process) or by lithography and RIE. It is possible that the VIAs 8 are fabricated after completion of the further planarization coat 17 through both planarization coats 2, 17 or also after completion of the first coat 2 sections thereof through the first planarization coat 2 and after completion of the second planarization coat 17 sections thereof through the second coat 17.

In step S7, the active element of the (respective) detector 3 given by a graphene film 13 is provided on the upper side 16 of the further planarization coat 17, for example deposited on the upper side 16.

The deposition of the graphene film 13 of the (respective) detector can be carried out, for example, by means of a transfer process as described in more detail above. Then, in particular, in each case a graphene film fabricated on a separate substrate or a separate metal foil or a separate germanium wafer is transferred to the further planarization coat 17. It is also possible that the (respective) graphene film 13 is fabricated directly on the further planarization coat 17. This may include, for example, a material deposition.

If a transfer process is used, it is possible that the passivation coat is already provided on the upper side of the respective graphene film 13, that this has been deposited thereon, for example, and is then transferred with it. Alternatively, a passivation coat may also be deposited after the graphene film(s) 13 has/have been transferred or fabricated.

It is also possible that first a full-area graphene film and/or a full-area passivation coat is fabricated on the further planarization coat 17, which extend over the entire surface of the further planarization coat 17. In this case, structuring is then still carried out, in particular by lithography and RIE, in order to obtain the individual graphene films 13 as active elements of several detectors 3.

The contact elements 18 are then fabricated (step S8), preferably by depositing metal over the entire surface and then again structuring by lithography and RIE to obtain the individual elements 18.

In a penultimate step S9, the upper passivation coat 19 preferably of Al₂O₃ and/or SiO₂ is deposited. In this coat, openings, in particular for contact elements, are then expediently fabricated by means of lithography and RIE (step S10). Preferably, openings are made to contact elements which serve to connect the photonics and/or electronics to the outside.

FIG. 3 shows a further embodiment of a photodetector 3 according to the first aspect of the invention.

This differs from that according to FIG. 1 essentially in that the two waveguide segments 12a, 12b of the longitudinal section 12 of the waveguide 11 do not have a rectangular cross-section and there is no further planarization coat 17, but instead the active element, which is also given here—by way of example—by a graphene film 13, is arranged on a dielectric coat provided on the gate electrodes 15a, 15b, which cannot be seen in the figure. The dielectric coat represents a gate dielectric. It is characterized on its upper side by a roughness of 0.2 nm RMS. Its thickness is 15 nm, wherein these two values are to be understood purely as examples.

As can be seen, each of the two waveguide segments 12a, 12b has an end region facing the gap 14 located between the two segments 12a, 12b, the cross-section of which widens in sections in the direction of the gap 14. As can be seen, the two end regions and the gap 14 form a central, trapezoidal region. The sections or regions of the segments 12a, 12b adjoining this trapezoidal region on both sides are characterized by a constant thickness, as can be seen.

The two gate electrodes 15a, 15b each extend in the transverse direction over only a section of the upper side of the respective segment 12a, 12b.

In FIG. 3, the VIAs 8 associated with the gate electrodes 15a, 15b and each in contact with a gate electrode 15a, 15b can be seen. Via these, a connection is made to at least one integrated electronical component 5 from the FEOL 6, but this is not visible in the figure for reasons of simplified representation. As can be seen, these VIAs 8 extend in each case through the planarization coat 2 and that waveguide segment 12a, 12b on which the respective gate electrode 15a, 15b is arranged. The voltage supply of the gate electrodes 15a, 15b is ensured via the VIAs 8. In the example shown in FIG. 3, too, a pn junction can be obtained in the graphene film 13 via the gate electrodes 15a, 15b during operation, again in the region extending above the gap 14 in which the optical mode is guided during operation.

To obtain the arrangement according to FIG. 3, the steps S1 to S3 can be identical to those for the fabrication of the arrangement of FIG. 1.

In step S4, an adapted etching process, in particular RIE process, is carried out for the fabrication of the waveguides 11 and gate electrodes 15, 15b, after the waveguide material has also been deposited here over the area, for example in the same way as described above in connection with FIG. 1, in order to obtain the trapezoidal region with the beveled edges. An isotropic etching behavior of the RIE process can be obtained for example by an increased process pressure and adapted gas mixture compared to the anisotropic etching process. The increased process pressure, for example 20 mTorr compared to 10 mTorr, gives the etching process an undirected component, which causes a higher removal rate at the upper edge due to the longer etching time. Subsequently, first the VIAs 8 for the gate electrodes 15a, 15b are fabricated and then again material for the gate electrodes 15a, 15b, such as silicon, is deposited.

Then the (respective) slot 14 and the gate electrodes 15a, 15b are etched. As a result, the gate electrode coat, which is initially full-surface, is “divided”.

Step S5 for the arrangement shown in FIG. 1 is omitted here, since no further planarization coat 17 is to be fabricated here. Therefore, the VIAs 8 for the graphene film 13 are fabricated in step S5 here.

In step S6, the dielectric coat is first fabricated on the upper side of the gate electrodes 15a, 15b and resist-planarized preferably on its upper side in order to achieve the aforementioned roughness, and then the graphene film 13 is provided thereon.

The trapezoidal shape ensures that the active element, in this case the graphene film 13, follows the gate electrodes 15a, 15b or the dielectric coat, in particular on the beveled edges. As a result, the graphene always lies on the dielectric coat on the electrodes 15a, 15b and can be electrostatically controlled particularly well. Also, a particularly homogeneous electric field can be achieved.

The steps following the provision of the (respective) graphene film 13 can correspond to those for the arrangement shown in FIG. 1 (in particular fabrication of the contact elements 18, fabrication of the passivation coat 19 and provision of openings therein).

FIG. 4 shows an embodiment of a photodetector according to the second aspect of the invention.

It also comprises a longitudinal section 12 of a waveguide 11, and an active element 13 comprising or consisting of at least one material which absorbs electromagnetic radiation of at least one wavelength and generates an electrical photosignal as a result of the absorption. Also, in the detector according to FIG. 3, the active element is—exemplarily—given by a graphene film 13.

Contrary to the examples in FIGS. 1 and 3, the waveguide 11 and its longitudinal section 12 belonging to the detector 3 are formed in one piece here. Specifically, it is a strip waveguide with a rectangular cross-section.

A further difference is given by the fact that two carrier elements 20 are arranged on opposite sides of the longitudinal section of the waveguide 11, being spaced therefrom forming two gaps 21. The carrier elements 20 are thereby arranged at a distance from the longitudinal section 12 of the waveguide 11 in the transverse direction. The two gaps 21 are free of material. Vacuum is present in them.

The carrier elements 20 can be made of the same material as the longitudinal section 12 of the waveguide 11, although this is to be understood as exemplarily.

The active element 13 overlaps, as can be seen, in the transverse direction the longitudinal section 12 of the waveguide 11 and the two gaps 21 and in sections the two carrier elements 20.

Furthermore, the graphene film 13 is planar, contrary to the examples of FIGS. 1 and 3, where it rests in a trapezoidal region.

As far as the wafer 1, the planarization coat 2 and the passivation coat 19 are concerned, the arrangement in FIG. 4 is identical to that in FIG. 2. As can be seen, it also has no further planarization coat 17. Furthermore, this detector 3 does not comprise gate electrodes.

To fabricate the arrangement of FIG. 4, steps S1 to S3 may again be identical to those described in connection with FIG. 1.

In a step S4, the waveguides 11 and carrier elements 20 are then fabricated. For this purpose, waveguide material, for example the same as in the previous examples, is deposited over the surface and then the gaps 21 are obtained by lithography and etching.

The VIAs 8 are fabricated then, extending here through the one planarization coat 2 and one of the carrier elements 20 each (step S5).

In a step S6, the active elements, for instance in the form of graphene films 13, are provided, which is expediently done by a transfer process as described in more detail above.

The remaining steps can again be the same as those that followed the provision of the active elements 13 in the previous examples (in particular, the fabrication of the contact elements 18, the fabrication of the passivation coat 19 and the provision of openings therein).

FIG. 5 shows an embodiment of an electro-optical modulator 22 according to the third aspect of the invention.

It also comprises a longitudinal section 12 of a waveguide 11, but comprising four waveguide segments 12a, 12b 12c, 12d extending in the longitudinal direction and at least substantially parallel to one another.

As it is a modulator 22, it further comprises two active elements 13a, 13b comprising at least one material or consisting of at least one material whose refractive index changes as a function of a voltage and/or the presence of charge and/or an electric field. In the example shown, the two active elements are given by two graphene films 13a, 13b.

Of the two active elements 13a, 13b, the lower one 13a is located on the upper side 10 of the planarization coat 2.

It should be noted that, alternatively to two active elements 13a, 13b being provided, only one active element and one conventional electrode, such as made of a metal, may be provided and arranged correspondingly to each other.

With respect to the four waveguide segments 12a-12d, it further applies that a lower one of the waveguide segments 12a is arranged between the two active elements 13a, 13b and a middle one of the waveguide segments 12b is arranged above the two active elements 13a, 13b, specifically on the upper active element 13b. In other words, there is a sandwich configuration (in FIG. 5 from bottom to top) of the first active element 13a, the lower waveguide segment 12a, the second active element 13b and the middle segment 12b. The upper active element 13b extends within the longitudinal section 12 of the waveguide. The waveguide segments 12a-12d may all be of the same material.

The lower and middle waveguide segments 12a, 12b serve simultaneously as passivation and etch protection. In particular, the segment 12a is part of the waveguide and also protection for the element 13a when the element 13b is etched. Then, waveguide segment 12a serves as an etch stop coat and as a passivation coat to protect the graphene 13a. In particular, segment 12b is also etch stop coat for structuring of parts 12c and 12d during fabrication of region 14.

The two remaining, upper waveguide segments 12c, 12d are arranged above the middle waveguide segment 12b, presently on its upper side. The two upper waveguide segments 12c, 12d are spaced apart from each other in the transverse direction forming a gap 14 extending therebetween. The two upper waveguide segments 12c, 12d thus lie side by side on the middle waveguide segment 12b and the gap 14 lies between them. It applies that exactly one gap 14 is provided above the two active elements 13. The gap 14 is filled with the material of the coat 19.

The extension of the lower and middle waveguide segments 12a, 12b in the transverse direction exceeds, as can be seen, the extension of the two upper segments 12c, 12d in this direction by a multiple. The cross-section of the segments 12a-12d is rectangular.

The two active elements 13a, 13b are spaced apart from each other—by the lower waveguide segment 12a—and, moreover, are offset from each other in the transverse direction in such a way that they lie one above the other in sections in an overlap region 23. A section of one active element 13 is aligned or overlapped with a section of the other active element 13. Specifically, the end regions facing each other are lying one above the other or are aligned, forming the overlap region 23. As can be seen from FIG. 5, the overlap region 23 lies below the gap 14 formed between the two segments 12c, 12d and is aligned therewith.

The extension of the overlap region 23 and the extension of the gap 14 in the transverse direction are adapted to each other. In concrete terms, the extension of the overlap region 23 in the transverse direction is approximately 1.3 times the extension of the gap 14 in this direction. For example, it can also correspond to 1.0 times or 0.8 times, i.e., have the same or a smaller extension in this direction. In particular, it applies that the smaller the overlap, the lower the capacitance and the faster the modulator.

Also, in the case of the modulator 22 with two active elements 13, it applies that the modulator, specifically its active elements 13, are connected to at least one integrated electronic component 5 from the FEOL of the wafer 1. Each active element 13 is connected to a VIA 8 by a contact element 18 associated therewith and in contact therewith, which VIA 8 extends through the planarization coat 2 (VIA 8 for the active element 13 on the left in FIG. 5) or the planarization coat 2 and the waveguide segment 12a (VIA 8 for the active element 13 on the right in FIG. 5) and, together with further VIAs 8 in the BEOL 7, ensures the connection.

An electro-optical modulator 22, as shown in FIG. 5 and also in FIGS. 6 and 7, which will be explained further on, can be used in a manner known per se, in particular for optical signal coding.

To obtain the arrangement of FIG. 5, the steps S1 to S3 can be identical.

Subsequently, in a step S4, the first, lower graphene film 13a can be provided as the lower active element. This can be done in the same way as described above for the one active element 13 of the detectors 3. Accordingly, this may comprise, for example, a full-area deposition of material and subsequent structuring.

Then the contact element 18 belonging to this active element 13 can be fabricated, again in exactly the same way as the contact elements 18 from FIGS. 1, 3 and 4.

In step S6, the lower waveguide segment 12a is then fabricated, which can preferably comprise material deposition and subsequent structuring—in analogy to the segments 12a, 12b from the previous figures. The same materials as mentioned for the previous embodiments can be used as waveguide material.

In step S7, the second, upper graphene film 13b is provided on the upper side of the segment 12a, preferably in the same way as the first, lower graphene film 13a.

In step S8, the contact element 18 is fabricated for it.

In step S9, the middle segment 12b is fabricated—preferably in the same way as the lower segment 12a—and in step S10 the two upper segments 12c, 12d are fabricated on top of the middle segment 12c. Again, a waveguide material can be deposited in the manner described above and then structured to obtain the two adjacent segments 12c, 12d enclosing the gap 14 between them. It should be noted that it is possible for the material deposition for the middle segment 12b and the upper two segments 12c, 12d to be interrupted or separate, for example when different waveguide materials are used. However, it is not excluded that the material required for the middle segment 12b and the material required for the upper segments 12c, 12d are applied in one deposition process, without interruption, and the segments 12b, 12c, 12d are obtained by subsequent structuring.

This is then preferably followed by the steps for obtaining the passivation coat 19 (S11) and the openings therein (S12), as explained above in connection with the preceding figures. The gap 14 fills with the material of the coat 19 during or due to the material deposition for the coat 19.

FIG. 6 shows an embodiment of a modulator 22 according to the fourth aspect of the invention.

It differs from that according to FIG. 5 in particular in that there is a gap 14 not above, but below the active elements 13, which are also given here—by way of example—by graphene films 13, and the longitudinal section 12 of the waveguide 11 does not comprise four, but five segments 12a, 12b, 12c, 12d, 12e.

In concrete terms, two lower ones of the waveguide segments 12a, 12b are arranged below the active elements 13 and are spaced apart from each other in the transverse direction forming a gap 14 extending therebetween, and a first middle one of the waveguide segments 12c is arranged between the two active elements 13, and a second middle waveguide segment 12d is arranged above the two active elements 13, specifically on the upper side of the upper active element 13, and an upper waveguide segment 12e is arranged above the second middle waveguide segment 12d, specifically on the upper side thereof. In this example, there is thus a sandwich-like structure comprising—from bottom to top—the two lower waveguide segments 12a, 12b, the lower active element 13a, a first middle waveguide segment 12c, the upper active element 13b, a second middle waveguide segment 12d and, on its upper side, the upper waveguide segment 12e. Here, both active elements 13 extend within the longitudinal section 12 of the waveguide 11.

Here, the two lower waveguide segments 12a, 12b and the first middle waveguide segment 12c serve also simultaneously as passivation and etch protection.

Concerning the extension of the gap 14 in the overlap region 23 in the transverse direction, the same applies as with respect to FIG. 5.

To obtain the arrangement of FIG. 6, the steps S1 to S3 can be identical again.

In a step S4, the two waveguide segments 12a, 12b are then first fabricated on the upper side 10 of the planarization coat 2, wherein waveguide material is deposited for this purpose, preferably exactly in the same way as in the preceding embodiments, whereby a continuous coat is initially obtained, and then the gap 14 is fabricated by structuring, which preferably includes lithography and etching, in particular RIE, and filled with a dielectric material, for example SiO2, and the surface is preferably planarized, for example by CMP and/or resist planarization.

Then, the VIA 8 associated with the left graphene film 13 in FIG. 5 can be fabricated (step S5), extending through the planarization coat 2 and the left one of the lower segments 12a in FIG. 5, which can be done as described above.

Next, the first, lower graphene film 13 is provided (step S6), which can also be done as in the previous examples. The lower graphene film 13 is preferably arranged in such a way that it completely overlaps the gap 14—as can be seen in FIG. 5—in the transverse direction.

Then, the associated contact element 18 can be fabricated as described above (step S6), and then the first middle waveguide segment 12c, the VIA 8 for the second, upper graphene film 13 (step S7), the second, upper graphene film 13(S8 ), as the first one, the second middle segment 12d (S9 ) and the upper segment 12e (S10 ). The fabrication of the segments 12c, 12d and 12e can be done, for example, analogously to the fabrication of the segments 12a to 12d of FIG. 5, with the difference that no gap is provided in the segment 12e, which is etched only as a strip-shaped segment with a rectangular cross-section.

Finally, the steps described above for obtaining the passivation coat 19 (S11 ) and the openings therein (S12) can also be carried out here.

FIG. 7 shows an embodiment of a modulator 22 according to the fifth aspect of the invention.

It differs from the example in FIG. 6 only in that a second gap 14 is additionally provided above the active elements, again by way of example, formed by graphene films 13. Instead of the strip-shaped waveguide segment 12e as in FIG. 6, two adjacent segments 12e and 12f spaced apart from one another to form the second gap 14 are also provided here above the graphene films 13 on the upper side of the second middle segment 12d. It should be noted that the second, upper gap 14 also fills with the material of the coat 19 in this case during or due to the deposition of the material for the coat 19.

In this example, there is a sandwich-like structure comprising—from bottom to top—the two lower waveguide segments 12a, 12b, the lower active element 13a, a first middle waveguide segment 12c, the upper active element 13b, a second middle waveguide segment 12d and, on its upper side two adjacent upper waveguide segments 12e, 12f. Again, both active elements 13 extend within the longitudinal section 12 of the waveguide 11.

The two lower waveguide segments 12a, 12b and the first middle waveguide segment 12c also serve here simultaneously as passivation and etching protection.

As can be seen in FIG. 6, the overlap region 23 formed by the two active elements 13 due to the offset is located above one gap 14, specifically between the lower segments 12a and 12b, and below the other gap 14, in concrete terms that one between the upper segments 12e and 12f.

The lower gap 14, the overlap region 23 and the upper gap 14 are aligned.

It further applies here that the extension of the overlap region 23 and the extension of both gaps 14 are adapted to each other in the transverse direction. Specifically, the extension of the overlap region 23 in the transverse direction is approximately 1.3 times the extension of the upper gap 14 and the lower gap 14 in this direction. For example, it may correspond also to 1.0 times or 0.8 times.

To obtain the arrangement of FIG. 7, the same procedure can be followed as for that of FIG. 6, with the only difference that the upper gap 14 must also be etched. As a result, the two upper segments 12e and 12f with the gap 14 therebetween are then obtained on the upper side of the second middle waveguide segment 12d instead of the one upper segment 12e.

As noted above, the examples of semiconductor devices according to the invention each include a plurality of photodetectors 3 or modulators 22, only one of which is shown by way of example in the partial sections. In the illustrated embodiments of semiconductor devices according to the invention, all photodetectors 3 or modulators 22 can be identical in design. The conformity then enables a particularly simple, rapid fabrication. It should be emphasized, however, that it is of course also possible for a semiconductor device according to the invention to comprise different embodiments of photodetectors 3 and/or modulators 22 shown in FIGS. 1 and 3 to 6, for example both detectors 3 according to FIG. 1 and modulators according to FIG. 5. There may also be more than two different embodiments, for example one or more of each of the photodetectors 3 and/or modulators 22 shown.

It should be noted that the respective arrangements provided on the wafer 1, which comprise the coats 2, possibly 17 and 19, as well as photodetectors 3 and/or modulators 22, may also each be considered and designated as a photonic platform. Furthermore, it should be noted that, alternatively to the photonic platform being fabricated on the BEOL 7 of the wafer 1 as in the described embodiments, it is also possible in principle for it to be fabricated separately and bonded to the wafer 1.

After completion of a semiconductor device according to the present invention, a plurality of semiconductor apparatuses, each formed by a chip with integrated photonics built thereon with one or more photodetectors 3 and/or modulators 22 according to the present invention, can be obtained therefrom in a simple and fast manner, specifically by mere dicing, in other words fragmenting.

The “bare chips” with photodetectors 3 and/or modulators 22 obtained by dicing can then, as it is also known from conventional bare chips, be inserted into packages and supplied for further use.

A chip obtained by dicing the semiconductor device with the wafer 1 and the photodetectors 3 and/or modulators 22 with one or more such is an embodiment of a semiconductor apparatus according to the invention.

It should be noted that all partial sectional views show only a comparatively very small section, specifically a section showing only a small part of the wafer 1 or a chip obtained after dicing. All partial sections thus represent sections both through an embodiment of a semiconductor device according to the invention and through an embodiment of a semiconductor apparatus according to the invention. Furthermore, it should be noted that already above a single chip a plurality of photodetectors 3 and/or modulators 22 can be provided, depending on the application, for example several tens, several hundreds or even several thousands.

1.-8. (canceled)

9. A modulator comprising a longitudinal section of a waveguide, which comprises or is formed by four waveguide segments extending in the longitudinal direction and at least substantially parallel to one another, and two active elements comprising or consisting of at least one material whose refractive index changes as a function of a voltage and/or the presence of charge and/or electric field, or one such active element and an electrode, wherein a lower one of the waveguide segments is arranged between the two active elements or between the active element and the electrode, a middle one of the waveguide segments is arranged above the two active elements or above the active element and the electrode and the two remaining, upper waveguide segments are arranged above the middle waveguide segment, wherein the two upper waveguide segments are spaced apart from each other forming a gap extending therebetween.

10. A modulator comprising a longitudinal section of a waveguide, which comprises or is formed by five waveguide segments extending in the longitudinal direction and at least substantially parallel to one another, and two active elements comprising or consisting of at least one material whose refractive index changes as a function of a voltage and/or the presence of charge and/or an electric field, or such an active element and an electrode, wherein two lower ones of the waveguide segments are arranged below the active elements or below the active element and the electrode and are spaced apart from each other forming a gap extending therebetween, and a first middle one of the waveguide segments is arranged between the two active elements or between the active element and the electrode, and a second middle waveguide segment is arranged above the two active elements or above the active element and the electrode, and an upper waveguide segment is arranged above the second middle waveguide segment.

11. A modulator comprising a longitudinal section of a waveguide, which comprises or is formed by six waveguide segments extending in the longitudinal direction and at least substantially parallel to one another, and two active elements comprising or consisting of at least one material whose refractive index changes as a function of a voltage and/or the presence of charge and/or an electric field, or such an active element and an electrode, wherein two lower ones of the waveguide segments are arranged below the active elements or below the active element and the electrode and are spaced apart from one another forming a gap extending therebetween, and a first middle one of the waveguide segments is arranged between the two active elements or between the active element and the electrode, and a second middle waveguide segment is arranged above the two active elements or above the active element and the electrode, and the two remaining upper waveguide segments are arranged above the second middle waveguide segment wherein the two upper waveguide segments are spaced apart from each other forming a gap extending therebetween.

12. The modulator according to claim 9, wherein the two active elements or the active element and the electrode are spaced apart from one another and are arranged offset from one another in such a way that they lie one above the other in sections thus forming an overlap region.

13. The modulator according to claim 9, wherein the overlap region is located above or below the gap.

14. The modulator according to claim 11, wherein the overlap region is located above one gap and below the other gap.

15. The modulator according to claim 9, wherein exactly one gap formed between two waveguide segments spaced apart from one another is provided above the two active elements or above the active element and the electrode, and/or in that exactly one gap formed between two waveguide segments spaced apart from one another is provided below the two active elements or below the active element and the electrode.

16. The modulator according to claim 9, wherein the extension of the overlap region in the transverse direction corresponds to the range from 0.8 times to 1.8 times of the extension of the gap or at least one of the gaps in the transverse direction.

17. The modulator according to claim 9, wherein the at least one material of at least one of the active elements whose refractive index changes as a function of a voltage and/or the presence of charge and/or an electric field, is graphene, and/or at least one dichalcogenide, and/or heterostructures of two-dimensional materials and/or germanium and/or lithium niobate and/or at least one electro-optical polymer and/or silicon and/or at least one compound semiconductor.

18.-23. (canceled)

24. The modulator according to claim 16, wherein the extension of the overlap region in the transverse direction corresponds to the range from 1.0 times to 1.5 times of the extension of the gap or at least one of the gaps in the transverse direction.

25. The modulator according to claim 17, wherein the at least one dichalcogenide is at least one two-dimensional transition dichalcogenide.

26. The modulator according to claim 17, wherein the at least one compound semiconductor is at least one II-VI semiconductor.

27. The modulator according to claim 17, wherein the at least one compound semiconductor is at least one III-V semiconductor.

28. The modulator according to claim 9, wherein the modulator is arranged on a chip or on a coat arranged on or above the chip.

29. The modulator according to claim 9, wherein the modulator is part of a photonic platform fabricated on a chip or bonded to the chip.

30. The modulator according to claim 9, wherein the modulator is arranged on a wafer or on a coat arranged on or above the wafer.
